(19) United States
(12) Patent Application Publication
(10) Pub. No.: US 2024/0194273 A1
(43) Pub. Date: Jun. 13, 2024

(54) NONVOLATILE MEMORY DEVICE, STORAGE DEVICE INCLUDING THE SAME, AND METHOD OF OPERATING THE SAME

(71) Applicant: Samsung Electronics Co., Ltd., Suwon-si (KR)

(72) Inventors: Chiweon Yoon, Suwon-si (KR); Chihyun Kim, Suwon-si (KR); Philkyu Kang, Suwon-si (KR); Junehong Park, Suwon-si (KR); Jayang Yoon, Suwon-si (KR); Hyeongdo Choi, Suwon-si (KR)

(21) Appl. No.: 18/239,480

(22) Filed: Aug. 29, 2023

(30) Foreign Application Priority Data
Dec. 7, 2022 (KR) 10-2022-0169558

(51) Int. Cl. G11C 16/30; G06F 1/20; G11C 16/04; G11C 16/08

(52) U.S. Cl. CPC G11C 16/30; G06F 1/206; G11C 16/0483; G11C 16/08

(57) ABSTRACT

A nonvolatile memory device comprising a charge pump circuit with pump units connected in series that receives an external voltage for charge pumping and outputs a pump voltage in stages according to stage control signals, a switching circuit that controls the charge pump circuit to output pumping voltages in response to switch control signals, a stage controller that outputs the stage control signals and the switch control signals based on a temperature code, and a digital temperature sensor that generates the temperature code.

### CROSS-REFERENCE TO RELATED APPLICATION(S)

This application claims benefit of priority under 35 U.S.C. § 119 to Korean Patent Application No. 10-2022-0169558 filed on Dec. 7, 2022 in the Korean Intellectual Property Office, the disclosure of which is incorporated herein by reference in its entirety.

### BACKGROUND

Example embodiments of the present disclosure relate to a nonvolatile memory device, a storage device including the same, and a method of operating the same.

Generally, a storage device including a nonvolatile memory device has been widely used in a universal serial bus (USB) drive, a digital camera, a mobile phone, a smartphone, a tablet, a PC, a memory card, a solid state drive (SSD), and the like. A storage device may be usefully used to store or move a large amount of data. Recently, a storage device has been miniaturized and implemented in an electronic device in embedded form.

### SUMMARY

An example embodiment of the present disclosure is to provide a nonvolatile memory device, a storage device including the same, and a method of operating the same.

An example embodiment of the present disclosure is to provide a nonvolatile memory device which may perform on-chip thermal throttling, a storage device including the same, and a method of operating the same.

According to an example embodiment of the present disclosure, a nonvolatile memory device includes a charge pump circuit including pump units connected in series configured to receive an external voltage and to perform a charge pumping operation, and configured to output a pump voltage by forming stages corresponding to the number of pump units connected in series in response to stage control signals; a switching circuit configured to control the charge pump circuit to output pumping voltages of the pump units in response to switch control signals; a stage controller configured to output the stage control signals and the switch control signals according to a temperature code; and a digital temperature sensor configured to generate the temperature code.

According to an example embodiment of the present disclosure, a method of operating a nonvolatile memory device includes sensing a temperature by a digital temperature sensor; determining a pump stage in response to a temperature code corresponding to the sensed temperature; and generating a wordline voltage using a pump voltage according to the determined pump stage.

According to an example embodiment of the present disclosure, a storage device includes at least one nonvolatile memory device; and a controller configured to control the at least one nonvolatile memory device, wherein the at least one nonvolatile memory device includes a plurality of memory blocks including a plurality of memory cells connected to wordlines and bitlines; a digital temperature sensor configured to sense a temperature of at least one predetermined region of the at least one nonvolatile memory device and to generate a temperature code; and a control logic circuit configured to perform an on-chip thermal throttling operation according to the temperature code, and wherein the on-chip thermal throttling operation controls timing of a wordline voltage applied to at least one of the wordlines.

According to an example embodiment of the present disclosure, a method of operating a nonvolatile memory device includes receiving a thermal throttling command from an external device; sensing a temperature of a predetermined region of the nonvolatile memory device in response to a thermal throttling command; and performing, on the nonvolatile memory device, an on-chip thermal throttling operation according to the sensed temperature.

### BRIEF DESCRIPTION OF DRAWINGS

The above and other aspects, features, and advantages of the present disclosure will be more clearly understood from the following detailed description, taken in combination with the accompanying drawings, in which:

FIG. 1 is a diagram illustrating a nonvolatile memory device according to an example embodiment of the present disclosure;

FIG. 2 is a circuit diagram illustrating a memory block (according to an example embodiment of the present disclosure;

FIG. 3 is a diagram illustrating a voltage generator according to an example embodiment of the present disclosure;

FIG. 4 is a diagram illustrating a charge pump circuit according to an example embodiment of the present disclosure;

FIGS. 5A and 5B are diagrams illustrating a thermal throttling method of the nonvolatile memory device according to an example embodiment of the present disclosure;

FIG. 6 is a diagram illustrating a digital temperature sensor according to an example embodiment of the present disclosure;

FIG. 7 is a diagram illustrating a voltage timing before on-chip thermal throttling of a nonvolatile memory device according to an example embodiment of the present disclosure;

FIG. 8 is a diagram illustrating voltage timing of on-chip thermal throttling of the nonvolatile memory device according to an example embodiment of the present disclosure;

FIG. 9 is a flowchart illustrating a method of operating a nonvolatile memory device 100 according to an example embodiment of the present disclosure;

FIG. 10 is a diagram illustrating a storage device according to an example embodiment of the present disclosure;

FIG. 11 is a diagram illustrating a controller according to an example embodiment of the present disclosure;

FIG. 12 is a ladder diagram illustrating a temperature management method of a storage device according to an example embodiment of the present disclosure;

FIG. 13 is a diagram illustrating a memory system according to an example embodiment of the present disclosure;

FIG. 14 is a diagram illustrating a memory device according to an example embodiment of the present disclosure; and

FIG. 15 is a diagram illustrating a data center to which a memory device is applied according to an example embodiment of the present disclosure.

### DETAILED DESCRIPTION

Hereinafter, embodiments of the present disclosure will be described as below with reference to the accompanying drawings.

Generally, when power consumption is increased without increasing a size of a storage device, the storage device may generate more heat and may cause a failure due to overheating. Thermal throttling may maintain a temperature of a storage device to be below a limit temperature. A nonvolatile memory device, a storage device including the same, and a method of operating the same in an example embodiment may perform effective thermal throttling in a memory chip using an on-chip temperature sensor. Also, the nonvolatile memory device in the example embodiment may perform on-chip thermal throttling by including a digital temperature sensor DTS, a stage charge pump, and a control logic.

A nonvolatile memory device, a storage device including the same, and a method of operating the same in an example embodiment may adjust a peak/average current by adjusting the number or timing of serial stages of the charge pump used for wordline setup according to the output of a digital temperature sensor DTS. Also, a nonvolatile memory device, a storage device including the same, and an operation method thereof in an example embodiment may enable optimal thermal throttling by controlling current consumption through an internal temperature sensor of the memory chip. Also, a nonvolatile memory device, a storage device including the same, and a method of operating the same in an example embodiment may effectively perform thermal throttling in a memory chip prior to performing on/off control of the memory chip in a system.

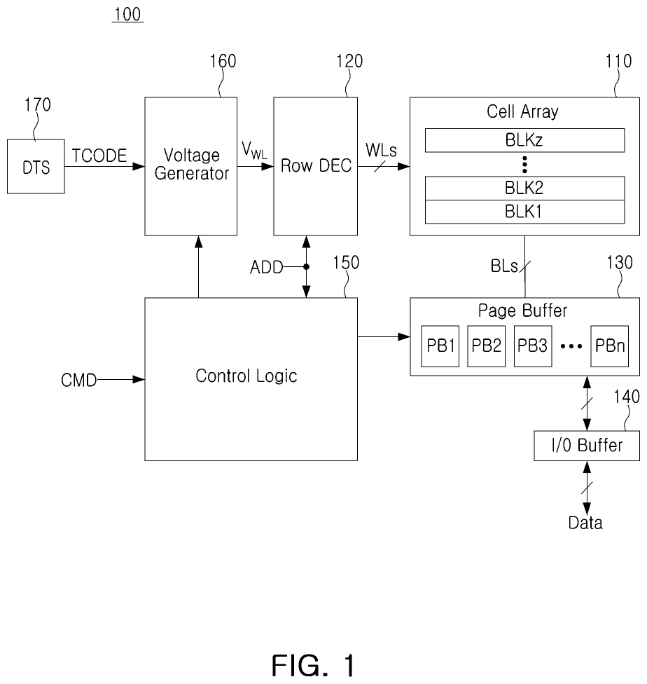

FIG. 1 is a diagram illustrating a nonvolatile memory device 100 according to an example embodiment. Referring to FIG. 1, the nonvolatile memory device 100 may include a memory cell array 110, a row decoder 120, a page buffer circuit 130, an input/output buffer circuit 140, a control logic circuit 150, a voltage generator 160, and a digital temperature sensor 170 (DTS).

The memory cell array 110 may be connected to the row decoder 120 through wordlines WLs or selection lines SSL and GSL. The memory cell array 110 may be connected to the page buffer circuit 130 through bitlines BLs. The memory cell array 110 may include a plurality of cell strings. Each channel of the cell strings may be formed in a vertical or horizontal direction. Each of the cell strings may include a plurality of memory cells. Here, the plurality of memory cells may be programmed, erased, or read by a voltage provided to a bitline BLs or a wordline WLs. Generally, program operations may be performed in page units, and erase operations may be performed in block units. The details of memory cells may be described in US registered U.S. Pat. Nos. 7,679,133, 8,553,466, 8,654,587, 8,559,235, and 9,536,970, the disclosures of which are incorporated in their entirety herein. In an example embodiment, the memory cell array 110 may include a three-dimensional (3D) memory cell array, and the 3D memory cell array may include a plurality of NAND strings disposed in row and column directions.

The row decoder 120 may select one of the memory blocks BLK1-BLKz of the memory cell array 110 in response to an address ADD. The row decoder 120 may select one of the wordlines of the selected memory block in response to the address ADD. The row decoder 120 may transmit the wordline voltage V_{WL} corresponding to the operation mode to the wordline of the selected memory block. During a program operation, the row decoder 120 may apply a program voltage and a verify voltage to a selected wordline, and may apply a pass voltage to an unselected wordline. During a read operation, the row decoder 120 may apply a read voltage to a selected wordline and may apply a read pass voltage to an unselected wordline.

The page buffer circuit 130 may operate as a write driver or a sense amplifier. During the program operation, the page buffer circuit 130 may apply a bitline voltage corresponding to data to be programmed to the bitlines of the memory cell array 110. During a read operation or a verification read operation, the page buffer circuit 130 may detect data stored in the selected memory cell through the bitline BL. Each of the plurality of page buffers included in the page buffer circuit 130 may be connected to at least one bitline.

The input/output buffer circuit 140 may provide external data to the page buffer circuit 130. The input/output circuit buffer 140 may provide an externally provided command CMD to the control logic circuit 150 (see FIG. 1). The input/output buffer circuit 140 may provide the externally provided address ADD to the control logic circuit 150 or the row decoder 120. Also, the input/output buffer circuit 140 may externally output data sensed and latched by the page buffer circuit 130.

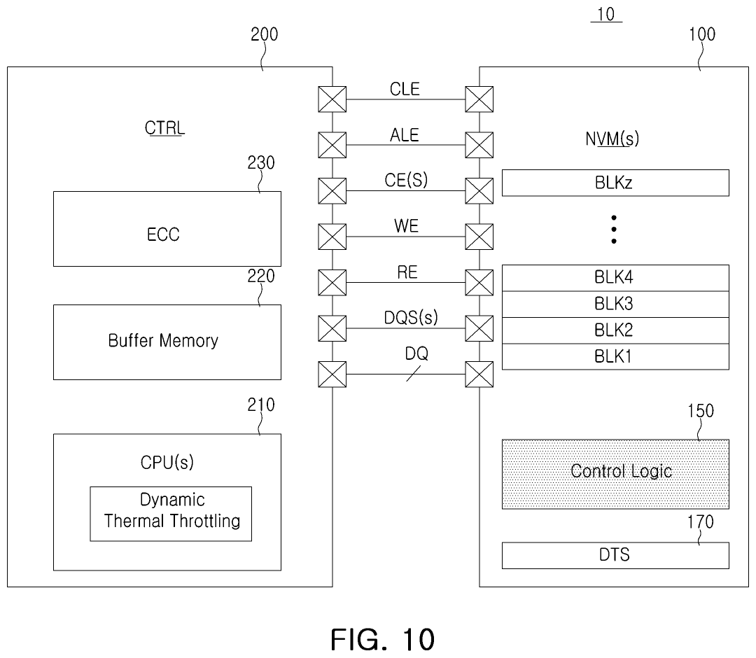

The control logic circuit 150 may control the row decoder 120, the page buffer circuit 130, and the voltage generator 160 in response to a command CMD transmitted from a controller 200 (See FIG. 10). Also, the control logic circuit 150 may perform a dynamic read operation based on cell count.

The voltage generator 160 may generate various types of wordline voltages to be applied to each of the wordlines under the control of the control logic circuit 150 and well voltages to be supplied to the bulk (e.g., well region) in which memory cells are formed. Wordline voltages applied to each wordline may include a program voltage, a pass voltage, a read voltage, and read pass voltages. A cell counter may count memory cells corresponding to a specific threshold voltage range from data sensed by the page buffer circuit 130. For example, the cell counter may count the number of memory cells including a threshold voltage within a specific threshold voltage range by processing data sensed by each of the plurality of page buffers PB1-PBn.

Also, the voltage generator 160 may perform a wordline setup operation differently depending on the temperature. For example, the voltage generator 160 may perform a wordline setup operation of performing thermal throttling according to a temperature code TCODE. In an example embodiment, the voltage generator 160 may vary the number of stages of the charge pump according to a temperature code TCODE in a wordline setup operation. In another example embodiment, the voltage generator 160 may adjust wordline setup timing according to a temperature code TCODE.

The digital temperature sensor 170 (DTS) may detect a temperature in at least one predetermined position of the nonvolatile memory device 100 and may generate a temperature code TCODE corresponding to the sensed temperature. Here, the at least one predetermined position may be an internal region of the memory cell array 110, the row decoder 120, or the page buffer circuit 130, or may be an external peripheral region of the memory cell array 110.

Also, the digital temperature sensor 170 may include a sensing unit for detecting a voltage/current signal proportional to temperature and an analog-to-digital converter for converting the detected voltage/current signal into a temperature code TCODE. Meanwhile, the temperature sensor in the example embodiment is not limited to a digital temperature sensor (DTS). The nonvolatile memory device in the example embodiment may include an analog temperature sensor.

The nonvolatile memory device 100 in an example embodiment may generate a temperature code TCODE using the digital temperature sensor 170, and may perform on-chip thermal throttling by varying the number of stages of the charge pump during the wordline setup operation according to the temperature code TCODE or adjusting the timing of the wordline setup operation.

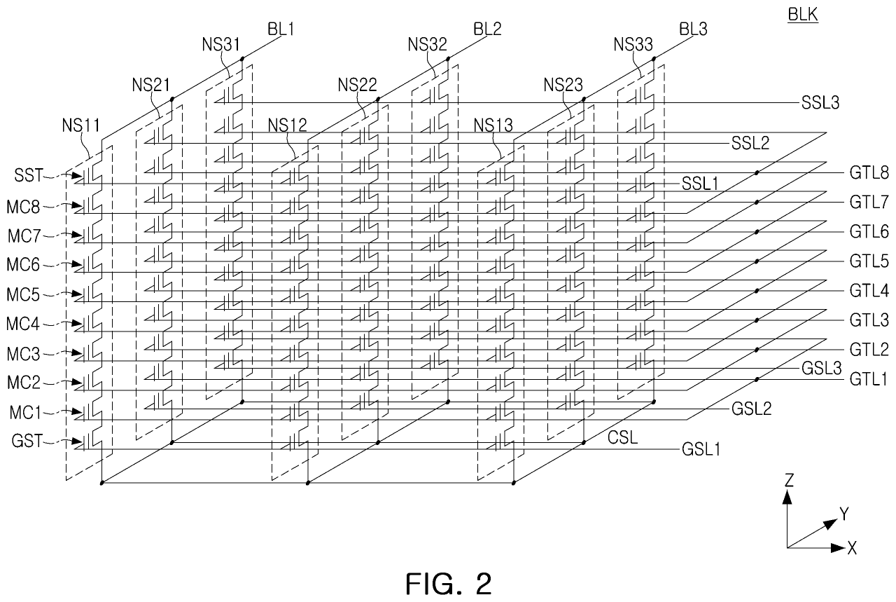

FIG. 2 is a circuit diagram illustrating an example memory block BLK of one of the plurality of memory blocks BLK1-BLKz according to an example embodiment. Referring to FIG. 2, the memory block BLK may include a plurality of memory NAND strings NS11-NS33 connected between bitlines BL1, BL2, and BL3 and a common source line CSL. Each of the plurality of memory NAND strings NS11-NS33 may include a string select transistor SST, a plurality of memory cells MC1, MC2, . . . , MC8, and a ground select transistor GST. Each of the plurality of memory NAND strings NS11-NS33 may include eighth memory cells MC1, MC2, . . . , MC8 in FIG. 2, but an example embodiment thereof is not limited thereto. The string select transistor SST may be connected to corresponding string selection lines SSL1, SSL2, and SSL3. The plurality of memory cells MC1, MC2, . . . , MC8 may be connected to corresponding gate lines GTL1, GTL2, . . . , GTL8, respectively. The gate lines GTL1, GTL2, . . . , GTL8 may correspond to wordlines, and a portion of the gate lines GTL1, GTL2, . . . , GTL8 may correspond to dummy wordlines. The ground select transistor GST may be connected to corresponding ground selection lines GSL1, GSL2, and GSL3. The string select transistor SST may be connected to the corresponding bitlines BL1, BL2, and BL3, and the ground select transistor GST may be connected to the common source line CSL. The wordlines (e.g., WL1) on the same level may be commonly connected, and ground selection lines GSL1, GSL2, and GSL3 and string selection lines SSL1, SSL2, and SSL3 may be separated from each other. The memory block BLK may be connected to eight gate lines GTL1, GTL2, . . . , GTL8 and three bitlines BL1, BL2, BL3 in FIG. 2, but an example embodiment thereof is not limited thereto.

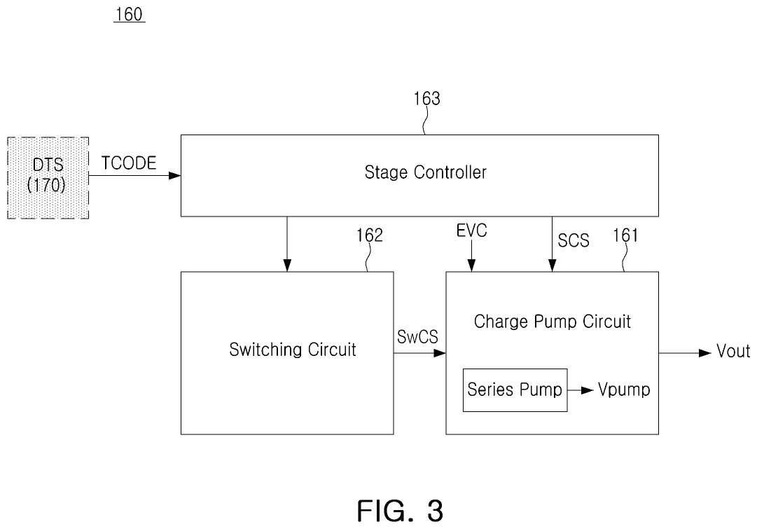

FIG. 3 is a diagram illustrating a voltage generator 160 according to an example embodiment. Referring to FIG. 3, the voltage generator 160 may include a charge pump circuit 161, a switching circuit 162, and a stage controller 163.

The charge pump circuit 161 may receive an external voltage EVC provided from an external device and may generate a pump voltage Vpump from the external voltage EVC.

The charge pump circuit 161 may include pump units connected in series which may receive the external voltage EVC and may perform a charge pumping operation, and may output a pump voltage Vpump by forming stages corresponding to the number of series-connected pump units in response to stage control signals SCS transmitted by the stage controller 163.

In an example embodiment, each of the plurality of pump units may receive an external voltage EVC and may perform a radiowave pumping operation. In an example embodiment, the number of pump units receiving external voltage EVC from among a plurality of pump units may vary according to the formed stage. For example, in the first stage, a pump unit may receive external voltage EVC, and in the second stage, two pump units may receive external voltage EVC.

The switching circuit 162 may transmit switch control signals SwCS to the charge pump circuit 161 to thereby control the charge pump circuit 161 to externally output the pump voltage Vpump output by the charge pump circuit 161 as an output voltage Vout. That is, the charge pump circuit 161 may output pumping voltages of pump units in response to switch control signals SwCS received from the switching circuit 162. For example, the charge pump circuit 161 may receive switch control signals SwCS and may output a pump voltage Vpump as an output voltage Vout. In this case, the switching circuit 162 may generate an output current to output an output voltage Vout.

The stage controller 163 may control a stage of the charge pump circuit 161. Also, the stage controller 163 may receive a temperature code TCODE from a digital temperature sensor (DTS) 170 and may vary the number of stages of the charge pump circuit 161 according to the temperature code TCODE. That is, the stage controller 163 may output stage control signals SCS and switch control signals SwCS according to the temperature code TCODE.

In the example embodiment, the stage controller 163 may vary the number of stages formed in the charge pump circuit 161 according to a temperature code TCODE. In the example embodiment, the stage controller 163 may form stages in the charge pump circuit 161 in which the number of pump units increasing per unit time may be the same, or may form stages in the charge pump circuit 161 in which the numbers of pump units increasing per unit time may be different. In the example embodiment, the stage controller 163 may vary the number of pump units included in a starting stage according to the temperature code TCODE. In the example embodiment, the stage controller 163 may output switch control signals SwCS per unit time. In the example embodiment, the unit time may vary according to the temperature code TCODE.

The stage controller 163 may be configured as a component of the voltage generator 160, but an example embodiment thereof is not limited thereto. The stage controller 163 in the example embodiment may be an internal component of the control logic circuit 150.

The voltage generator 160 in the example embodiment may adjust the number of stages of the charge pump circuit 161 according to the temperature code TCODE, thereby controlling the peak current/average current according to the wordline voltage generation.

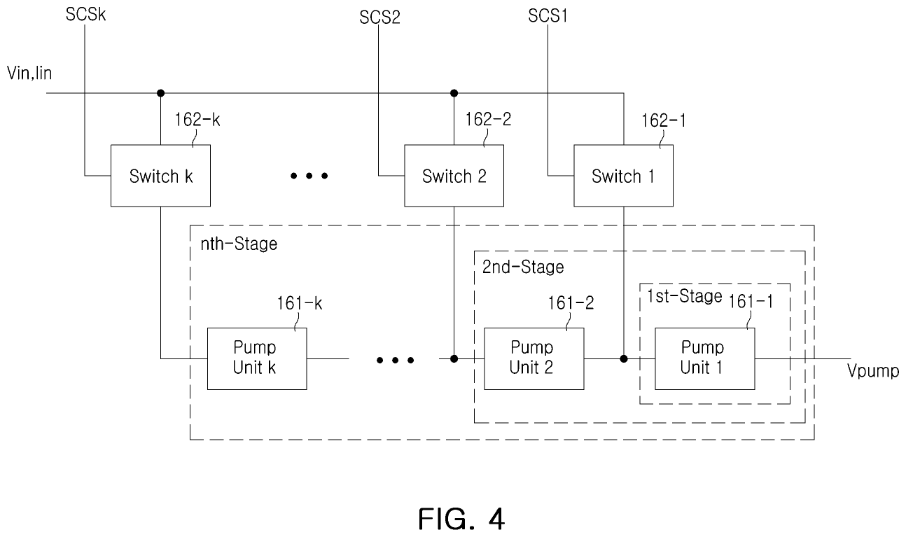

FIG. 4 is a diagram illustrating a charge pump circuit 161 according to an example embodiment. Referring to FIG. 4, the charge pump circuit 161 may include a plurality of pump units 161-1 to 161-k (where k is an integer of 2 or greater). Here, a plurality of pump units 161-1 to 161-k may be consecutively connected to each other.

The plurality of voltage switches 162-1 to 162-k may be switched such that an input voltage Vin is applied to a corresponding pump unit. By applying the stage control signals SCS1-SCSk corresponding to each of the plurality of voltage switches 162-1 to 162-k, the on/off operation of the plurality of voltage switches 162-1 to 162-k may be controlled. In this case, depending on the stage control signal SCS1-SCSk received from the stage controller 163, each of the voltage switches 162-1 to 162-k may be turned on and off.

In the example embodiment, the stage control signal may consist of a k-bit code (SCS1-SCSk), and each bit may correspond to different switches among the plurality of voltage switches 162-1 to 162-k. For example, among the stage control signals, the first code SCS1 may be provided to the first voltage switch 162-1, the second code SCS1 may be provided to the second voltage switch 162-2, and the n-th code SCSk may be provided to the n-th voltage switch 162-k.

In another example embodiment, the stage control signal SCS may not consist of a k-bit code, and may include a stage up signal for increasing the stage of the charge pump circuit 161 and a stage down signal for decreasing the stage of the charge pump circuit 161. The charge pump circuit 161 may increase the number of operating pump units by one when a stage-up signal is received, and may decrease the number of operating pump units by one when a stage-down signal is received.

Depending on the received stage control signal, the number of stages operating in the charge pump circuit 161 may be changed. Depending on the stage of the charge pump circuit 161, the number of pump units to which the input voltage Vin is applied may vary among the plurality of pump units 161-1 to 161-k. For example, in the first stage, the input voltage Vin may be applied to the first pump unit 161-1 such that one of the pump units may be driven. In the second stage, the input voltage Vin may be applied to the first pump unit 161-1 and the second pump unit 161-2 such that the two pump units may be driven. In the n-th stage, the input voltage Vin may be applied to the first to n-th pump units 161-1 to 161-k, such that n number of pump units may be driven.

As the number of driving pump units increases, the charge pump circuit 161 may generate a high voltage at a target level while outputting a relatively large amount of pump current Ipump. Accordingly, as the number of driving pump units increases, the time required for the pump voltage Vpump to reach a target level (e.g., setup time) may be reduced. As the number of driving pump units increases, power consumption of the charge pump circuit 161 may increase. Also, as the number of driving pump units increases, the peak value of the input current Iin input to the charge pump circuit 161 may increase.

The nonvolatile memory device 100 in the example embodiment may, by adjusting the number of operating pump units among the plurality of pump units 161-1 to 161-k included in the charge pump circuit 161 according to the temperature code TCODE, prevent unnecessary power consumption or may manage excessively long setup time.

The nonvolatile memory device 100 in the example embodiment may perform thermal throttling in a chip using an on-chip digital temperature sensor (DTS). The nonvolatile memory device 100 may control the number of serial stages and timing of a charge pump for determining current efficiency according to a temperature code TCODE of the digital temperature sensor (DTS). For example, the nonvolatile memory device 100 may monitor the internal temperature of a memory chip with a digital temperature sensor (DTS) and may change the number of serial stages and timing of the high voltage charge pump used in wordline setup according to the temperature code TCOD corresponding to the monitoring result, thereby controlling initial continuous current ICC and a peak current. Here, changing the number of series stages in the charge pump may have a significant effect on the current efficiency.

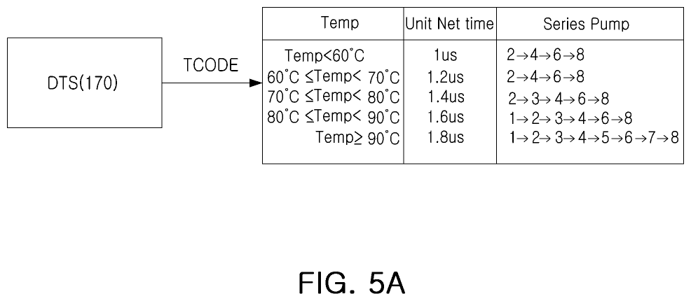

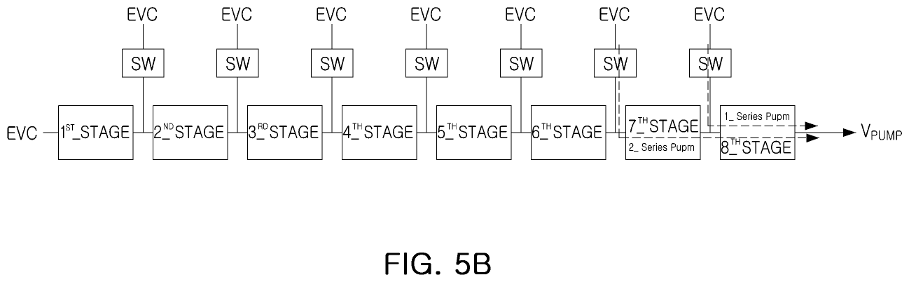

FIGS. 5A and 5B are diagrams illustrating a thermal throttling method of the nonvolatile memory device 100 according to an example embodiment.

FIG. 5A illustrates a pump control table according to the temperature of the memory chip. When the temperature of the memory chip is less than 60° C., the number of stages of the charge pump may be changed from 2 to 4, from 4 to 6, or from 6 to 8 per unit net time. Here, the unit net time required to change the number of stages may be 1 s. When the temperature of the memory chip is greater than 60° C. and less than 70° C., the number of stages of the charge pump may be changed from 2 to 4, from 4 to 6, or from 6 to 8 per unit net time. Here, the unit net time required to change the number of stages may be 1.2 s.

When the temperature of the memory chip is from 70° C. or more to less than 80° C., the number of stages of the charge pump may change from 2 to 3, from 3 to 4, from 4 to 6, and from 6 to 8 per unit net time. Here, the unit net time required to change the number of stages may be 1.4 s. When the temperature of the memory chip is between 80° C. and less than 90° C., the number of charge pump stages per unit net time may change from 1 to 2, 2 to 3, 3 to 4, 4 to 6, 6 to 8. Here, the unit net time required to change the number of stages may be 1.6 s. When the temperature of the memory chip is 90° C. or higher, the number of stages of the charge pump per unit net time may change from 1 to 2, 2 to 3, 3 to 4, 4 to 5, 5 to 6, 6 to 7, and 7 to 8. Here, the unit net time required to change the number of stages may be 1.8 s.

Meanwhile, the sequence of unit net time and serial number in the example embodiment may be changed in various combinations.

As illustrated in FIG. 5B, the charge pump circuit may consist of eight stages connected in series. Referring to FIG. 5B, stages may be activated by one of a 1-serial pump operation and a 2-serial pump operation.

The nonvolatile memory device 100 in the example embodiment may perform optimal thermal throttling by managing current consumption earlier than a thermal throttling point in time at which a memory chip is turned on/off by a memory controller.

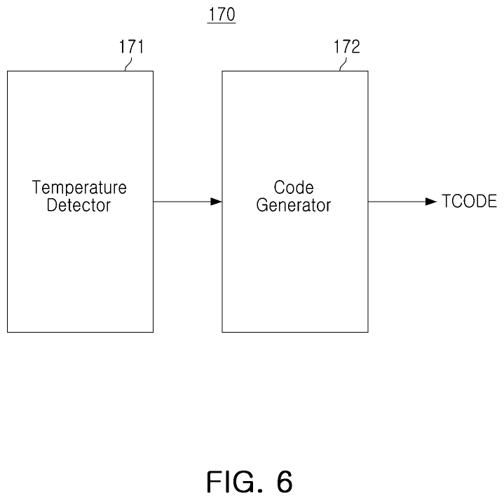

FIG. 6 is a diagram illustrating a digital temperature sensor 170 according to an example embodiment. Referring to FIG. 6, the digital temperature sensor 170 may include a temperature detector 171 and a code generator 172.

The temperature detector 171 may detect a voltage signal and a current signal corresponding to temperature.

The code generator 172 may generate a temperature code TCODE corresponding to the detected voltage/current signal. The code generator 172 may include an analog to digital converter.

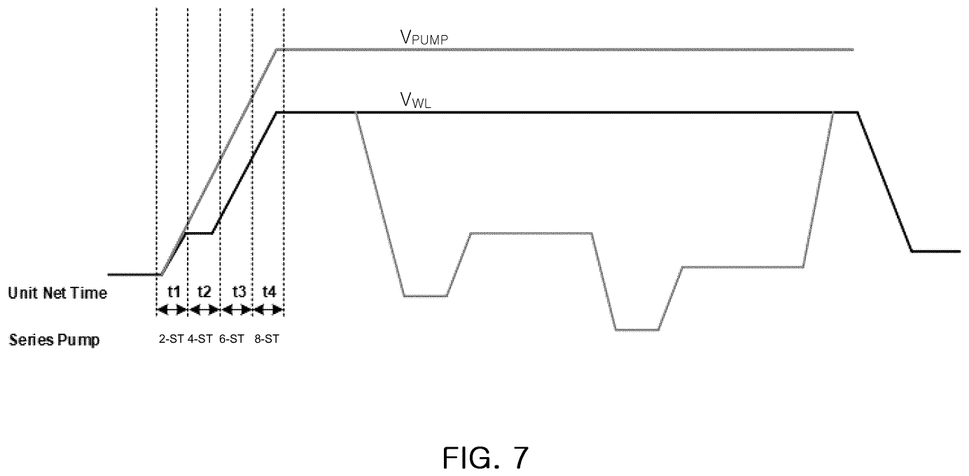

FIG. 7 is a diagram illustrating a voltage timing before on-chip thermal throttling of a nonvolatile memory device 100 according to an example embodiment. Referring to FIG. 7, a pump voltage Vpump prior to on-chip thermal throttling may be generated by activating two pump units per unit net time of four stages in sequence. Each of the unit net times t1-t4 may be the same.

The wordline voltage V_{WL} may be output as a required voltage by appropriately using the level of the pump voltage Vpump. At the second unit net time t2, the wordline voltage V_{WL} may maintain a constant level.

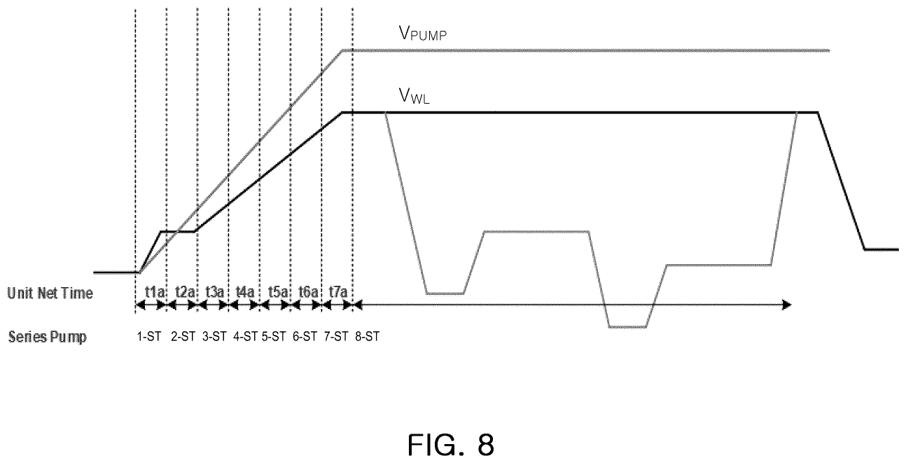

FIG. 8 is a diagram illustrating voltage timing of on-chip thermal throttling of the nonvolatile memory device 100 according to an example embodiment. Referring to FIG. 8, timings of a pump voltage Vpump and a wordline voltage V_{WL} may be changed differently from the examples illustrated in FIG. 7 according to on-chip thermal throttling.

Also, as illustrated in FIG. 8, the pump voltage Vpump may be generated according to an 8-stage series pump stage as compared to the example illustrated in FIG. 7. Also, the number of unit net times t1a-t7 and an interval therebetween may be different.

As illustrated in FIG. 8, the time to reach the target level of the pump voltage Vpump according to thermal throttling may be longer than the example in FIG. 7.

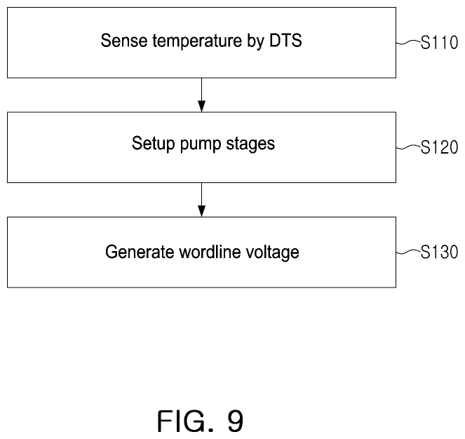

FIG. 9 is a flowchart illustrating a method of operating a nonvolatile memory device 100 according to an example embodiment. Referring to FIGS. 1 to 9, the nonvolatile memory device 100 may operate as below.

The temperature of the nonvolatile memory device 100 may be sensed by a digital temperature sensor (DTS, 170 in FIG. 1) of the nonvolatile memory device 100 (S110). A pump stage may be determined according to the detected temperature (S120). In the example embodiment, the pump stage may be determined by determining the number of pump units connected in series. In the example embodiment, the pump stage may be changed for each unit time. In the example embodiment, unit time may be varied according to a temperature code TCODE. A pump voltage Vpump may be generated based on the determined pump stage, and a wordline voltage V_{WL} required for driving may be generated using the generated pump voltage Vpump. The generated wordline V_{WL} may be applied to a corresponding wordline (S130). In the example embodiment, the wordline voltage V_{WL} may be generated by dividing a pump voltage Vpump into a resistor.

FIG. 10 is a diagram illustrating a storage device 10 according to an example embodiment. Referring to FIG. 10, the storage device 10 may include at least one nonvolatile memory device 100 NVM(s) and a controller 200 CTRL.

The at least one nonvolatile memory device 100 may store data. The nonvolatile memory device 100 may be implemented as a NAND flash memory, a vertical NAND flash memory, a NOR flash memory, a resistive random access memory (RRAM), a phase-change memory (PRAM), a magnetoresistive random access memory (MRAM), a ferroelectric random access memory (FRAM), a spin transfer torque random access memory (STT-RAM), or the like.

Also, the nonvolatile memory device 100 may include a plurality of memory blocks BLK1-BLKz (where z is an integer greater than or equal to 2), a control logic circuit 150, and a digital temperature sensor 170. Each of the plurality of memory blocks BLK1 to BLKz may include a plurality of pages Page 1-Page m (where m is an integer greater than or equal to 2). Each of the plurality of pages Page 1 to Page m may include a plurality of memory cells. Each of the plurality of memory cells may store at least one bit.

The control logic circuit 150 may receive a command and an address from the controller (CTRL; 200), and may perform an operation (program operation, read operation, erase operation, or the like) corresponding to the received command on memory cells corresponding to the address. The control logic circuit 150 may vary an operation condition according to temperature.

The digital temperature sensor 170 may sense the temperature of the nonvolatile memory device 100.

The nonvolatile memory device 100 in the example embodiment may control the serial number or timing of the charge pump using the temperature code TCODE of the digital temperature sensor 170.

The controller 200 CTRL may be connected to at least one nonvolatile memory device 100 through a plurality of control pins used to transmit control signals (e.g., CLE, ALE, CE(s), WE, RE, or the like). Also, the controller 200 may control the nonvolatile memory device 100 using control signals (CLE, ALE, CE(s), WE, RE, or the like). For example, the nonvolatile memory device 100 may perform a program operation/read operation/erase operation latching a command CMD or an address ADD at the edge of a write enable WE signal according to a command latch enable CLE signal and an address latch enable ALE signal. For example, during a read operation, the chip enable signal CE may be activated, CLE may be activated during the command transmission period, ALE may be activated during the address transmission period, and RE may be toggled in a period in which data is transmitted through the data signal line DQ. The data strobe signal DQS may toggle at a frequency corresponding to the data input/output rate. Read data may be sequentially transmitted in synchronization with the data strobe signal DQS.

Also, the controller 200 may include at least one processor 210 (central processing unit (CPU)(s)), a buffer memory 100, and an error correction circuit 230.

The CPU 210 may control overall operation of the storage device 10. The CPU 210 may perform various management operations such as cache/buffer management, firmware management, garbage collection management, wear leveling management, data deduplication management, read refresh/reclaim management, bad block management, multi-stream management, host data and nonvolatile memory mapping. management, quality of service (QoS) management, system resource allocation management, nonvolatile memory queue management, read level management, erase/program management, hot/cold data management, power loss protection management, dynamic thermal throttling, initialization management, and redundant array of inexpensive disks (RAID) management.

Also, the processor 210 may drive a dynamic thermal throttling (DTT) module. In the example embodiment, the DTT module may manage heat of the storage device 10 according to temperature information. Here, the temperature information may be transmitted from the nonvolatile memory device 100 or may be generated in the controller 200.

The buffer memory 220 may be implemented as a volatile memory (e.g., static random access memory (SRAM), dynamic RAM (DRAM), synchronous RAM (SDRAM), or the like) or a nonvolatile memory (flash memory, phase-change PRAM (PRAM), or the like) RAM), magneto-resistive RAM (MRAM), resistive RAM (ReRAM), ferro-electric RAM (FRAM), or the like).

The ECC circuit 230 may generate an error correction code during a program operation and may restore data using the error correction code during a read operation. That is, the ECC circuit 230 may generate an error correction code (ECC) for correcting a fail bit or an error bit of the data received from the nonvolatile memory device 100. The ECC circuit 230 may form data to which parity bits are added by performing error correction encoding on data provided to the nonvolatile memory device 100. Parity bits may be stored in the nonvolatile memory device 100.

Also, the ECC circuit 230 may perform error correction decoding on data output by the nonvolatile memory device 100. The ECC circuit 230 may correct errors using parity. The ECC circuit 230 may correct an error using a coded modulation such as a low density parity check (LDPC) code, BCH code, turbo code, reed-Solomon code, convolution code, recursive systematic code (RSC), trellis-coded modulation (TCM), or block coded modulation (BCM).

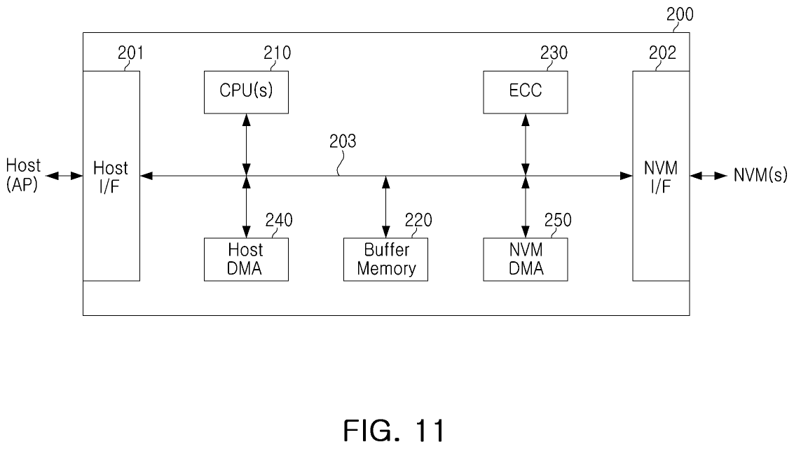

FIG. 11 is a diagram illustrating a controller 200 according to an example embodiment. Referring to FIG. 11, the controller 200 may include a host interface circuit 201, a nonvolatile memory interface circuit 202, a bus 203, at least one processor 210 (CPU(s)), a buffer memory 220, an error correction circuit 230 (ECC), a host DMA circuit 240 and a nonvolatile memory DMA circuit 250.

The host interface circuit 201 may transmit a packet to and may receive a packet from the host. A packet transmitted from the host to the host interface circuit 201 may include a command or data to be written to the nonvolatile memory 100. A packet transmitted from the host interface circuit 201 to the host may include a response to a command or data read from the nonvolatile memory 100.

The nonvolatile memory interface circuit 202 may transmit data to be written to the nonvolatile memory 100 to the nonvolatile memory 100 or may receive data read from the nonvolatile memory 100. The nonvolatile memory interface circuit 202 may comply with standard protocols such as JEDEC (Joint Electron Device Engineering Council) Toggle or ONFI (Open NAND Flash Interface).

The packet manager may generate a packet according to a protocol of an interface negotiated with the host or may parse various types of information from a packet received from the host. The encryption device may perform at least one of an encryption operation and a decryption operation on data input to the controller 200 using a symmetric-key algorithm. The encryption device may encrypt and decrypt data using an advanced encryption standard (AES) algorithm. The encryption device may include an encryption module and a decryption module. In the example embodiment, the cryptographic device may be implemented in terms of hardware/software/firmware. The encryption device may perform a self-encryption disk (SED) function or a trusted computing group (TCG) security function. The SED function may store encrypted data in the nonvolatile memory device 100 using an encryption algorithm or may decrypt encrypted data from the nonvolatile memory device 100. The encryption/decryption operation may be performed using an internally generated encryption key. The TCG security function may provide a mechanism enabling access control to user data of the storage device 100. For example, the TCG security function may perform an authentication procedure between the external device and the storage device 100. In the example embodiment, the SED function or the TCG security function may be selected optionally.

The host DMA circuit 240 may control a DMA operation between the host and the controller 200. The host DMA circuit 240 may perform an operation of storing data input from the host through the host interface 201 in the buffer memory 220 during a program operation under the control of the host controller. Also, the host DMA circuit 240 may perform an operation of outputting data stored in the buffer memory 220 to the host through the host interface 201 during a read operation. In the example embodiment, the host DMA circuit 240 may be included in the host controller as a component of the host controller.

The nonvolatile memory DMA circuit 250 may control a DMA operation between the controller 200 and the nonvolatile memory device 100. The nonvolatile memory DMA circuit 250 may perform an operation of outputting data stored in the buffer memory 220 to the nonvolatile memory device 100 through the nonvolatile memory interface circuit 202 during a program operation under the control of a nonvolatile memory controller. Also, the nonvolatile memory DMA circuit 250 may perform an operation of reading data stored in the nonvolatile memory device 100 through the nonvolatile memory interface circuit 202 during a read operation.

Also, the nonvolatile memory DMA circuit 250 may receive at least one data group divided into read transfer units from the nonvolatile memory interface circuit 202 during a read operation. The nonvolatile memory DMA circuit 250 may divide each data group into at least two data subgroups having a smaller data size unit than a read transfer unit. Here, the divided data subgroups may be error-corrected data by the error correction circuit 230. In the example embodiment, when the first read pass is selected, at least two divided data subgroups may be transmitted to the host DMA circuit 240. In another example embodiment, when the second read pass is selected, at least two divided data subgroups may be sequentially transmitted to the buffer memory 220.

Also, when transmitting data subgroups to the buffer memory 220, the nonvolatile memory DMA circuit 250 may output information indicating the start of read streaming to the buffer controller. For example, the nonvolatile memory DMA circuit 250 may be included in the nonvolatile memory controller as a component of the nonvolatile memory controller.

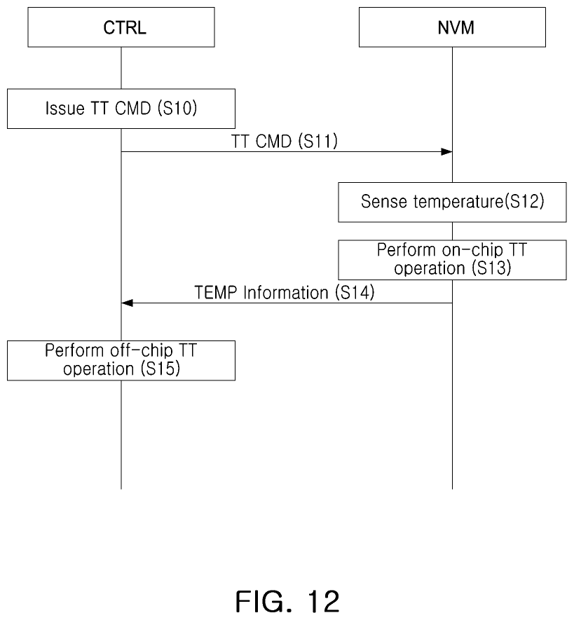

FIG. 12 is a ladder diagram illustrating a temperature management method of a storage device according to an example embodiment.

Referring to FIG. 12, a temperature management method of a storage device may include an on-chip thermal throttling operation performed by a nonvolatile memory device NVM and an off-chip thermal throttling operation performed by a controller CTRL.

The controller CTRL may issue a thermal throttling command based on an internal policy or an external request (S10). The controller CTRL may transmit a thermal throttling command to a nonvolatile memory device NVM (S11). The nonvolatile memory device NVM may detect a temperature in response to a thermal throttling command (S12). The nonvolatile memory device NVM may perform an on-chip thermal throttling operation based on temperature information (S13). Thereafter, the nonvolatile memory device NVM may detect the temperature again and may output the sensed temperature information to the controller CTRL (S14). For example, the nonvolatile memory device NVM may out a temperature value (e.g., degree) to the controller CTRL. The controller CTRL may determine whether to perform an off-chip thermal throttling operation based on the temperature information received from the nonvolatile memory device NVM and may perform the off-chip thermal throttling operation (S15).

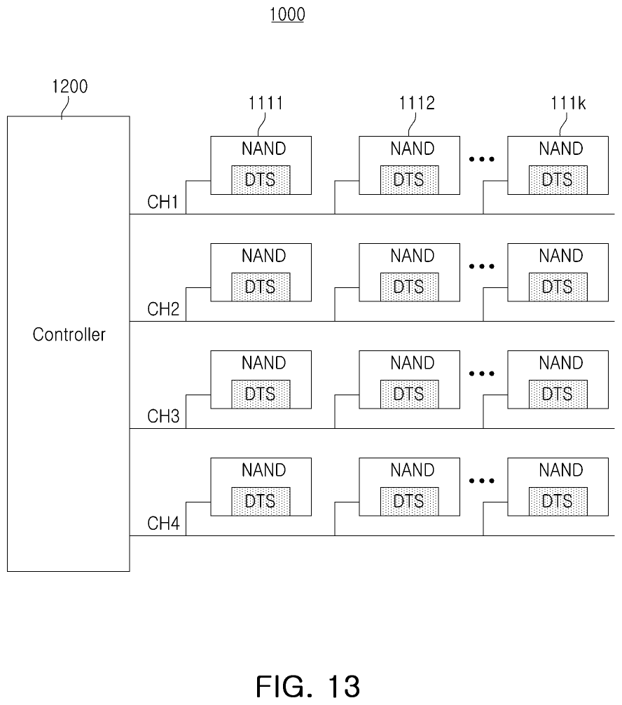

FIG. 13 is a diagram illustrating a memory system 1000 according to an example embodiment. Referring to FIG. 13, a memory system 1000 may include a plurality of NAND flash memory devices 1111, 1112, . . . , 111k connected to each of a plurality of channels CHI to CH4, and a controller 1200 for controlling the same.

Each of the plurality of NAND flash memory devices 1111, 1112, . . . , 111k may include a digital temperature sensor (DTS). Each of the plurality of NAND flash memory devices 1111, 1112, . . . , 111k may perform an on-chip thermal throttling operation, as illustrated in FIGS. 1 to 12.

In the example embodiment, program time (tPROG), read time (tR), or erase time (tERS) may be different for each channel according to on-chip thermal throttling operation.

Meanwhile, the nonvolatile memory device according to the example embodiment may have a chip to chip (C2C) structure.

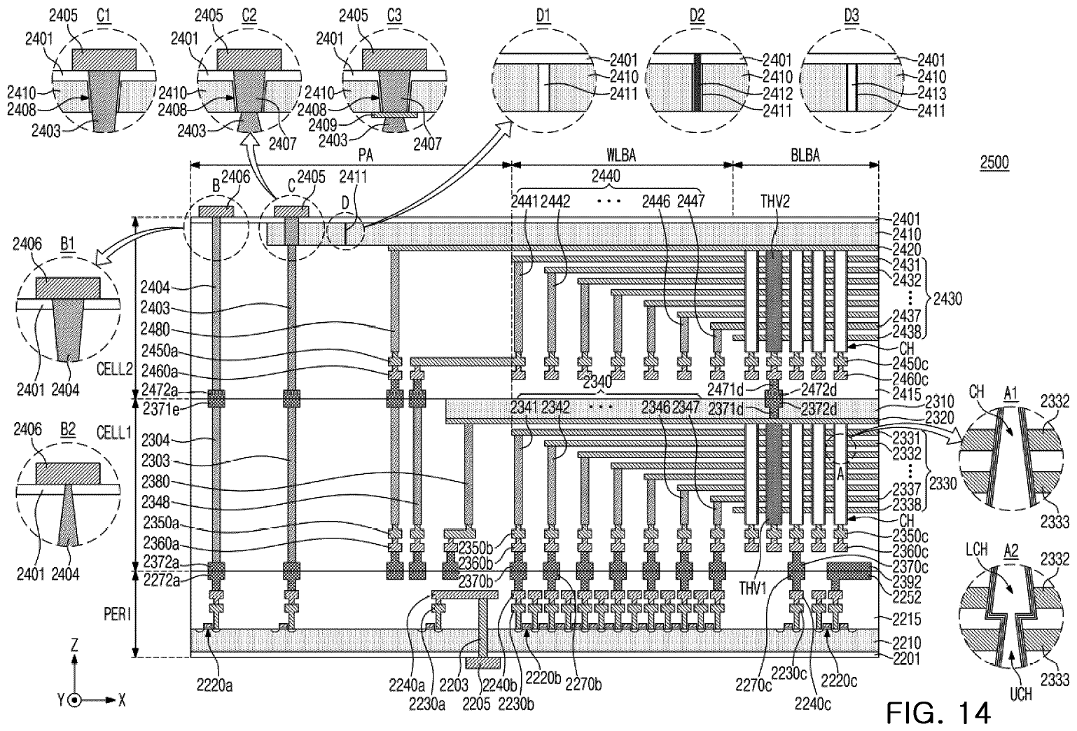

FIG. 14 is a diagram illustrating a memory device 2500 according to an example embodiment. Referring to FIG. 14, the memory device 2500 may have a C2C structure. Here, in the C2C structure, at least one upper chip including a cell region (CELL) and a lower chip including a peripheral circuit region PERI may be formed, and the at least one upper chip and the lower chip may be connected to each other by a bonding method. For example, the bonding method may refer to a method of electrically or physically connecting a bonding metal pattern formed on an uppermost metal layer of an upper chip and a bonding metal pattern formed on an uppermost metal layer of a lower chip. For example, when the bonding metal patterns are formed of copper (Cu), the bonding method may be a Cu—Cu bonding method. As another example, the bonding metal patterns may also be formed of aluminum (Al) or tungsten (W).

The memory device 2500 may include at least one upper chip including a cell region. For example, as illustrated in FIG. 14, the memory device 2500 may include two upper chips. However, this is merely an example, and the number of upper chips is not limited thereto. When the memory device 2500 is implemented to include two upper chips, the first upper chip including the first cell region CELL1, the second upper chip including the second cell region CELL2, the first upper chip, the second upper chip, and the lower chip may be connected to each other by a bonding method, such that a memory device 2500 may be manufactured. The first upper chip may be reversed and connected to the lower chip by bonding, and the second upper chip may also be reversed and connected to the first upper chip by bonding. In the description below, upper and lower portions of the first and second upper chips may be defined before the first upper chip and the second upper chip are reversed. That is, in FIG. 14, the upper portion of the lower chip may refer to the upper portion defined based on the +Z-axis direction, and the upper portion of each of the first and second upper chips may refer to the upper portion defined based on the −Z-axis direction. However, this is merely an example, and only one of the first upper chip and the second upper chip may be reversed and connected to each other by a bonding method.

Each of the peripheral circuit region PERI and the first and second cell regions CELL1 and CELL2 of the memory device 2500 may include an external pad bonding region PA, a wordline bonding region WLBA, and a bitline bonding region BLBA.

The peripheral circuit region PERI may include a first substrate 2210 and a plurality of circuit elements 2220a, 2220b, and 2220c formed on the first substrate 2210. An interlayer insulating layer 2215 including one or more insulating layers may be provided on the plurality of circuit elements 2220a, 2220b, and 2220c, and a plurality of metal wires connecting the plurality of circuit elements 2220a, 220b, and 220c may be provided in the interlayer insulating layer 2215. For example, the plurality of metal wires may include first metal wires 2230a, 2230b, and 2230c connected to the plurality of circuit elements 2220a, 2220b, and 2220c, respectively, and second metal wires 2240a, 2240b formed on the first metal wires 2230a, 2230b, 2230c, and 2240c. The plurality of metal wires may be formed of at least one of various conductive materials. For example, the first metal wires 2230a, 2230b, and 2230c may be formed of tungsten including a relatively high electrical resistivity, and the second metal wires 2240a, 2240b, and 2240c may be formed of copper including a relatively low electrical resistivity.

In the example embodiment, only the first metal wire 2230a, 2230b, and 2230c and the second metal wire 2240a, 2240b, and 2240c are described, but an example embodiment thereof is not limited thereto, and the second metal wire (2240a, 2240b, 2240c), at least one additional metal wire may be further formed. In this case, the second metal wires 2240a, 2240b, and 2240c may be formed of aluminum. Also, at least a portion of the additional metal wires formed on the second metal wires 2240a, 2240b, and 2240c may be formed of copper including a lower electrical resistivity than that of aluminum of the second metal wires 2240a, 2240b, and 2240c.

The interlayer insulating layer 2215 may be disposed on the first substrate 2210 and may include an insulating material such as silicon oxide or silicon nitride.

Each of the first and second cell regions CELL1 and CELL2 may include at least one memory block. The first cell region CELL1 may include a second substrate 2310 and a common source line 2320. A plurality of wordlines 2331 to 2338 (2330) may be stacked on the second substrate 2310 in a direction (Z-axis direction) perpendicular to the upper surface of the second substrate 2310. String selection lines and ground selection lines may be disposed above and below the wordlines 2330, and a plurality of wordlines 2330 may be disposed between the string selection lines and the ground selection lines. Similarly, the second cell region CELL2 may include a third substrate 2410 and a common source line 2420, and a plurality of wordlines 2431 to 2438 (2430) may be stacked in a direction perpendicular to the upper surface of the third substrate 2410 (Z-axis direction). The second substrate 2310 and the third substrate 2410 may be formed of various materials, and may be, for example, a silicon substrate, a silicon-germanium substrate, a germanium substrate, or a substrate having a monocrystalline epitaxial layer grown on a monocrystalline silicon substrate. A plurality of channel structures CHs may be formed in each of the first and second cell regions CELL1 and CELL2.

In an example embodiment, as illustrated in A1, the channel structure CH may be provided in the bitline bonding region BLBA, may extend in a direction perpendicular to the upper surface of the second substrate 2310 and may penetrate through wordlines 2330, string selection lines, and ground selection lines. The channel layer may be electrically connected to the first metal wire 2350c and the second metal wire 2360c in the bitline bonding region BLBA. For example, the second metal wire 2360c may be a bitline and may be connected to the channel structure CH through the first metal wire 2350c. The bitline 2360c may extend in a first direction (Y-axis direction) parallel to the upper surface of the second substrate 2310.

In an example embodiment, as illustrated in A2, the channel structure CH may include a lower channel LCH and an upper channel UCH connected to each other. For example, the channel structure CH may be formed through a process for a lower channel LCH and a process for an upper channel UCH. The lower channel LCH may extend in a direction perpendicular to the upper surface of the second substrate 2310 and may penetrate through the common source line 2320 and the lower wordlines 2331 and 2332. The lower channel LCH may include a data storage layer, a channel layer, and a buried insulating layer, and may be connected to the upper channel UCH. The upper channel UCH may penetrate through upper wordlines 2333-2338. The upper channel UCH may include a data storage layer, a channel layer, a buried insulating layer, and the like, and the channel layer of the upper channel UCH may be electrically connected to the first metal wire 2350c and the second metal wire 2360c. As the length of the channel increases, it may be difficult to form a channel including a constant width due to process reasons. The memory device 2500 in the example embodiment may include a channel having improved width uniformity through a lower channel LCH and an upper channel UCH formed through a sequential process.

As illustrated in A2, when the channel structure CH is formed to include a lower channel LCH and an upper channel UCH, a word disposed adjacent to the boundary of the lower channel LCH and the upper channel UCH line may be a dummy wordline. For example, the wordline 2332 and wordline 2333 forming the boundary between the lower channel LCH and the upper channel UCH may be dummy wordlines. In this case, data may not be stored in memory cells connected to the dummy wordline. Alternatively, the number of pages corresponding to memory cells connected to a dummy wordline may be less than the number of pages corresponding to memory cells connected to a general wordline. The voltage level applied to the dummy wordline may be different from the voltage level applied to the general wordline, and accordingly, the effect of the non-uniform channel width between the lower channel LCH and upper channel UCH on the operation of the memory device may be reduced.

In A2, the number of lower wordlines 2331 and 2332 through which the lower channel LCH penetrates may be less than the number of upper wordlines 2333-2338 through which the upper channel UCH penetrates. However, this is merely an example, and an example embodiment thereof is not limited thereto. As another example, the number of lower wordlines penetrating through the lower channel LCH may be equal to or greater than the number of upper wordlines penetrating through the upper channel UCH. Also, the structure of the channel structure CH disposed in the first cell region CELL1 and connection relationship thereof described above may also be applied to the channel structure CH disposed in the second cell region CELL2.

In a bitline bonding region BLBA, a first through electrode THV1 may be provided in a first cell region CELL1, and a second through electrode THV2 may be provided in a second cell region CELL2. As illustrated in FIG. 14, the first through electrode THV1 may penetrate through the common source line 2320 and the plurality of wordlines 2330. However, this is merely an example, and the first through electrode THV1 may further penetrate through the second substrate 2310. The first through electrode THV1 may include a conductive material. Alternatively, the first through electrode THV1 may include a conductive material surrounded by an insulating material. The second through electrode THV2 may also be provided in the same shape and structure as those of the first through electrode THV1.

In an example embodiment, the first through electrode THV1 and the second through electrode THV2 may be electrically connected to each other through a first through metal pattern 2372d and a second through metal pattern 2472d. The first through metal pattern 2372d may be formed on the lower end of the first upper chip including the first cell region CELL1, and the second through metal pattern 2472d may be formed on an upper end of the second upper chip including the second cell region CELL2. The first through electrode THV1 may be electrically connected to the first metal wire 2350c and the second metal wire 2360c. A lower via 2371d may be formed between the first through electrode THV1 and the first through metal pattern 2372d, and an upper via 2471d may be formed between the second through electrode THV2 and the second through metal pattern 2472d. The first through metal pattern 2372d and the second through metal pattern 2472d may be connected to each other by a bonding method.

Also, in the bitline bonding region BLBA, an upper metal pattern 2252 may be formed on the uppermost metal layer of the peripheral circuit region PERI, and an upper metal pattern 2392 having the same shape as that of the upper metal pattern 2252 may be formed in the uppermost metal layer of the first cell region CELL1. The upper metal pattern 2392 of the first cell region CELL1 and the upper metal pattern 2252 of the peripheral circuit region PERI may be electrically connected to each other by a bonding method. In the bitline bonding region BLBA, the bitline 2360c may be electrically connected to a page buffer included in the peripheral circuit region PERI. For example, a portion of the circuit elements 2220c of the peripheral circuit region PERI may provide a page buffer, and the bitline 2360c may be electrically connected to circuit elements 2220c providing a page buffer through an upper bonding metal 2370c of the first cell region CELL1 and an upper bonding metal 2270c of the peripheral circuit region PERI.

Referring to FIG. 14, in the wordline bonding region WLBA, the wordlines 2330 of the first cell region CELL1 may extend in a second direction (X-axis direction) parallel to the upper surface of the second substrate 2310 and may be connected to a plurality of cell contact plugs 2341-2347 (2340). A first metal wire 2350b and a second metal wire 2360b may be connected in order to the upper portion of the cell contact plugs 2340 connected to the wordlines 2330. The cell contact plugs 2340 may be connected to the peripheral circuit region PERI through the upper bonding metal 2370b of the first cell region CELL1 and the upper bonding metal 2270b of the peripheral circuit region PERI in the wordline bonding region WLBA.

The cell contact plugs 2340 may be electrically connected to a row decoder included in a peripheral circuit region PERI. For example, a portion of the circuit elements 2220b of the peripheral circuit region PERI may provide a row decoder, and the cell contact plugs 2340 may be electrically connected to the circuit elements 2220b providing the row decoder through the upper bonding metal 2370b of the first cell region CELL1 and the upper bonding metal 2270b of the peripheral circuit region PERI. In an example embodiment, the operation voltage of the circuit elements 2220b providing the row decoder may be different from the operation voltage of the circuit elements 2220c providing the page buffer. For example, an operation voltage of circuit elements 2220c providing a page buffer may be greater than an operation voltage of circuit elements 2220b providing a row decoder.

Similarly, in the wordline bonding region WLBA, the wordlines 2430 of the second cell region CELL2 may extend in a second direction (X-axis direction) parallel to the upper surface of the third substrate 2410, and may be connected to a plurality of cell contact plugs 2441-447 (2440). The cell contact plugs 2440 may be connect to the peripheral circuit region PERI through the upper metal pattern of the second cell region CELL2, the lower and upper metal patterns of the first cell region CELL1, and the cell contact plug 2348.

In the wordline bonding region WLBA, an upper bonding metal 2370b may be formed in the first cell region CELL1, and an upper bonding metal 2270b may be formed in the peripheral circuit region PERI. The upper bonding metal 2370b of the first cell region CELL1 and the upper bonding metal 2270b of the peripheral circuit region PERI may be electrically connected to each other by a bonding method. The upper bonding metal 2370b and the upper bonding metal 2270b may be formed of aluminum, copper, or tungsten.

In the external pad bonding region PA, a lower metal pattern 2371e may be formed in the lower portion of the first cell region CELL1, and an upper metal pattern 2472a may be formed in the upper portion of the second cell region CELL2. The lower metal pattern 2371e of the first cell region CELL1 and the upper metal pattern 2472a of the second cell region CELL2 may be connected to each other by a bonding method in the external pad bonding region PA. Similarly, an upper metal pattern 2372a may be formed above the first cell region CELL1, and an upper metal pattern 2272a may be formed above the peripheral circuit region PERI. The upper metal pattern 2372a of the first cell region CELL1 and the upper metal pattern 2272a of the peripheral circuit region PERI may be connected to each other by a bonding method.

Common source line contact plugs 2380 and 2480 may be disposed in the external pad bonding region PA. The common source line contact plugs 2380 and 2480 may be formed of a conductive material such as metal, metal compound, or doped polysilicon. The common source line contact plug 2380 of the first cell region CELL1 may be electrically connected to the common source line 2320, and the common source line contact plug 2480 of the second cell region CELL2 may be electrically connected to the common source line 2420. A first metal wire 2350a and a second metal wire 2360a may be stacked in order on the common source line contact plug 2380 of the first cell region CELL1, and the first metal wire 2450a and the second metal wire 2460a may be stacked in order on the common source line contact plug 2480 of the second cell region CELL2.

Input/output pads 2205, 2405, and 2406 may be disposed in the external pad bonding region PA. Referring to FIG. 14, a lower insulating film 2201 may cover the lower surface of the first substrate 2210, and a first input/output pad 2205 may be formed on the lower insulating film 2201. The first input/output pad 2205 may be connected to at least one of the plurality of circuit elements 2220a arranged in the peripheral circuit region PERI through the first input/output contact plug 2203, and may be separated from the first substrate 2210 by a lower insulating film 2201. Also, a side surface insulating film may be disposed between the first input/output contact plug 2203 and the first substrate 2210 and may electrically separate the first input/output contact plug 2203 and the first substrate 2210.

An upper insulating film 2401 covering an upper surface of the third substrate 2410 may be formed above the third substrate 2410. A second input/output pad 2405 and/or a third input/output pad 2406 may be disposed on the upper insulating film 2401. The second input/output pad 2405 may be connected to at least one of a plurality of circuit elements 2220a disposed in a peripheral circuit region PERI through second input/output contact plugs 2403 and 2303, and the third input/output pad 2406 may be connected to at least one of the plurality of circuit elements 2220a disposed in the peripheral circuit region PERI through the third input/output contact plugs 2404 and 2304.

In an example embodiment, the third substrate 2410 may not be disposed in a region in which input/output contact plugs are disposed. For example, as illustrated in B, the third input/output contact plug 2404 may be separated from the third substrate 2410 in a direction parallel to the upper surface of the third substrate 2410, and may penetrate through the interlayer insulating layer 2415 of the second cell region CELL2 and may be connected to the third input/output pad 2406. In this case, the third input/output contact plug 2404 may be formed through various processes.

For example, as illustrated in B1, the third input/output contact plug 2404 may extend in a third direction (Z-axis direction) and may have a diameter increasing toward the upper insulating film 2401. That is, while the diameter of the channel structure CH in A1 may decrease toward the upper insulating film 2401, the diameter of the third input/output contact plug 2404 may increase toward the upper insulating film 2401. For example, the third input/output contact plug 2404 may be formed after the second cell region CELL2 and the first cell region CELL1 are coupled to each other by a bonding method.

As an example, as illustrated in B2, the third input/output contact plug 2404 may extend in the third direction (Z-axis direction) and may have a diameter decreasing toward the upper insulating film 2401. That is, the diameter of the third input/output contact plug 2404 may decrease toward the upper insulating film 2401 similarly to the channel structure CH. For example, the third input/output contact plug 2404 may be formed together with the cell contact plugs 2440 before bonding the second cell region CELL2 to the first cell region CELL1.

In another example embodiment, the input/output contact plug may be disposed to overlap the third substrate 2410. For example, as illustrated in C, the second input/output contact plug 2403 may penetrate through the interlayer insulating layer 2415 of the second cell region CELL2 in the third direction (Z-axis direction), and may be electrically connected to the second input/output pad 2405 through the third substrate 2410. In this case, the connection structure between the second input/output contact plug 2403 and the second input/output pad 2405 may be implemented in various manners.

For example, as illustrated in C1, an opening 2408 penetrating through the third substrate 2410 may be formed, and a second input/output contact plug 2403 may be directly connected to the second input/output pad 2405 through an opening 2408 formed in the third substrate 2410. In this case, as illustrated in C1, the diameter of the second input/output contact plug 2403 may increase toward the second input/output pad 2405. However, this is merely an example, and the diameter of the second input/output contact plug 2403 may decrease toward the second input/output pad 2405.

For example, as illustrated in C2, an opening 2408 penetrating the third substrate 2410 may be formed, and a contact 2407 may be formed in the opening 2408. One end of the contact 2407 may be connected to the second input/output pad 2405, and the other end may be connected to the second input/output contact plug 2403. Accordingly, the second input/output contact plug 2403 may be electrically connected to the second input/output pad 2405 through the contact 2407 in the opening 2408. In this case, as illustrated in C2, the diameter of the contact 2407 may increase toward the second input/output pad 2405, and the diameter of the second input/output contact plug 2403 may decrease toward the second input/output pad 2405. For example, the third input/output contact plug 2403 may be formed together with the cell contact plugs 2440 before bonding the second cell region CELL2 to the first cell region CELL1, and the contact 2407 may be formed after bonding of the second cell region CELL2 to the first cell region CELL1.

As an example, as illustrated in C3, a stopper 2409 may be further formed on the upper surface of the opening 2408 of the third substrate 2410 as compared to C2. The stopper 2409 may be a metal wire formed on the same layer as the common source line 2420. However, this is merely an example, and the stopper 2409 may be a metal wire formed on the same layer as at least one of the wordlines 2430. The second input/output contact plug 2403 may be electrically connected to the second input/output pad 2405 through the contact 2407 and the stopper 2409.

Meanwhile, similarly to the second and third input/output contact plugs 2403 and 2404 of the second cell region CELL2, each of the second and third input/output contact plugs 2303 and 2304 may have a diameter decreasing toward the lower metal pattern 2371e or may have a diameter increasing toward the lower metal pattern 2371e.

Meanwhile, in example embodiments, a slit 2411 may be formed in the third substrate 2410. For example, the slit 2411 may be formed in an arbitrary position of the external pad bonding region PA. For example, as illustrated in D, the slit 2411 may be disposed between the second input/output pad 2405 and the cell contact plugs 2440 on a plane. However, this is merely an example, and the slit 2411 may be formed such that the second input/output pad 2405 may be disposed between the slit 2411 and the cell contact plugs 2440 on a plane.

For example, as illustrated in D1, the slit 2411 may be formed to penetrate through the third substrate 2410. The slit 2411 may be used, for example, to prevent the third substrate 2410 from being finely split when the opening 2408 is formed. However, this is merely an example, and the slit 2411 may be formed to have a depth of about 60 to 70% of the thickness of the third substrate 2410.

Also, as an example, as illustrated in D2, a conductive material 2412 may be formed in the slit 2411. The conductive material 2412 may be used, for example, to discharge leakage current generated during driving of circuit elements in an external pad bonding region PA to the outside. In this case, the conductive material 2412 may be connected to an external ground line.

Also, as an example, as illustrated in D3, an insulating material 2413 may be formed in the slit 2411. The insulating material 2413 may be formed to electrically isolate the second input/output pad 2405 and the second input/output contact plug 2403 disposed in the external pad bonding region PA from the wordline bonding region WLBA. By forming the insulating material 2413 in the slit 2411, the voltage provided through the second input/output pad 2405 may be prevented from affecting the metal layer disposed on the third substrate 2410 in the wordline bonding region WLBA.

Meanwhile, in example embodiments, the first to third input/output pads 2205, 405, and 406 may be selectively formed. For example, the memory device 2500 may include only a first input/output pad 2205 disposed on a first substrate 2201, a second input/output pad 2205 disposed on a third substrate 2410, or a third input/output pad 2406 disposed on the upper insulating film 2401.

In example embodiments, at least one of the second substrate 2310 of the first cell region CELL1 and the third substrate 2410 of the second cell region CELL2 may be used as a sacrificial substrate, and may be completely or partially removed before or after the bonding process. An additional film may be deposited after removing the substrate. For example, the second substrate 2310 of the first cell region CELL1 may be removed before or after bonding of the peripheral circuit region PERI to the first cell region CELL1, and an insulating film covering the upper surface of the common source line 2320 or a conductive film for connection may be formed. Similarly, the third substrate 2410 of the second cell region CELL2 may be removed before or after bonding of the first cell region CELL1 and the second cell region CELL2, and an upper insulating film 2401 covering the upper surface of the common source line 2420 or a conductive film for connection may be formed.

The storage device in the example embodiment is applicable to a data server system.

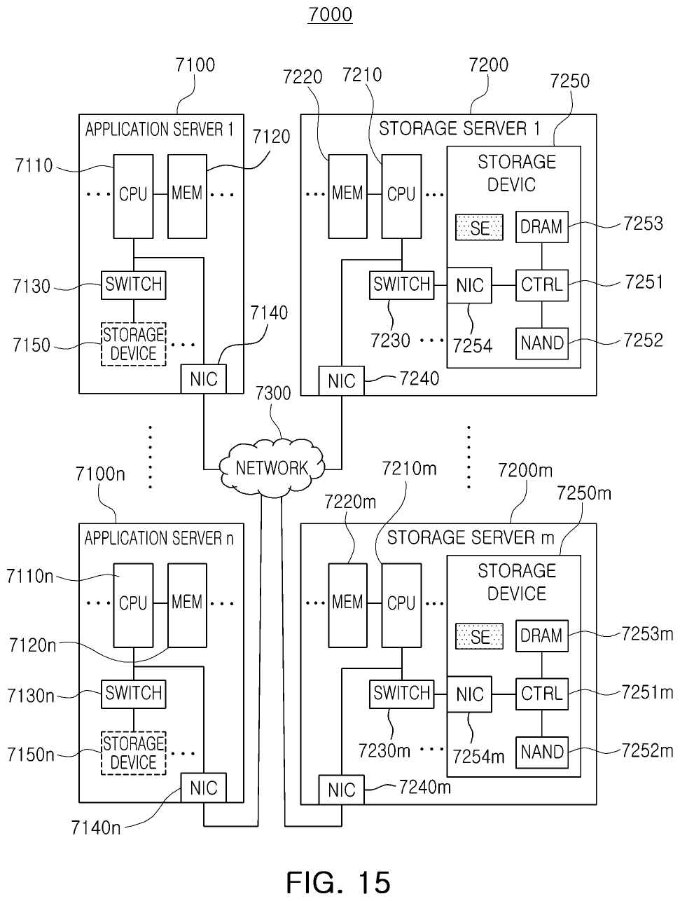

FIG. 15 is a diagram illustrating a data center to which a memory device is applied according to an example embodiment. Referring to FIG. 15, a data center 7000 may include application servers 7100-7100n and storage servers 7200-7200m. The number of application servers 7100-7100n and the number of storage servers 7200-7200m may be varied in example embodiments, and the number of application servers 7100 to 7100n and the number of storage servers 7200 to 7200m may be different.

The application server 7100 or the storage server 7200 may include at least one of processors 7110 and 7210 and memories 7120 and 7220. For example, the processor 7210 may control the overall operation of the storage server 7200, may access the memory 7220, and may execute instructions or data loaded into the memory 7220. The memory 7220 may be implemented as DDR double data rate synchronous DRAM (SDRAM), high bandwidth memory (HBM), hybrid memory cube (HMC), dual in-line memory module (DIMM), Optane DIMM, or nonvolatile DIMM (NVMDIMN). In example embodiments, the number of processors 7210 and memories 7220 included in the storage server 7200 may be varied. In an example embodiment, the processor 7210 and memory 7220 may provide a processor-memory pair. In the example embodiment, the number of processors 7210 and the number of memories 7220 may be different. The processor 7210 may include a single-core processor or a multi-core processor. The description of the storage server 7200 described above may be similarly applied to the application server 7100. In example embodiments, the application server 7100 may not include the storage device 7150. The storage server 7200 may include at least one storage device 7250. The number of storage devices 7250 included in the storage server 7200 may be varied in example embodiments.

The application servers 7100-7100n and the storage servers 7200-7200m may communicate with each other through the network 7300. The network 7300 may be implemented using fiber channel (FC) or Ethernet. In this case, FC may be a medium used for relatively high-speed data transmission, and an optical switch providing high performance/high availability may be used. Depending on an access method of the network 7300, the storage servers 7200 to 7200m may be provided as file storage media, block storage media, or object storage media.

In an example embodiment, network 7300 may be implemented as a storage only network, such as a storage area network (SAN). For example, the SAN may be an FC-SAN using an FC network and implemented according to FC Protocol (FCP). As another example, the SAN may be an IP-SAN using a TCP/IP network and implemented according to the iSCSI (SCSI over TCP/IP or Internet SCSI) protocol. In another example embodiment, network 7300 may be a generic network, such as a TCP/IP network. For example, the network 7300 may be implemented according to protocols such as FC over Ethernet (FCoE), network attached storage (NAS), and NVMe over fabrics (NVMe-oF). The description of the application server 7100 may also be applied to other application servers 7100n, and the description of the storage server 7200 may also be applied to other storage servers 7200m.

The application server 7100 may store data requested by a user or client to be stored in one of the storage servers 7200-7200m through the network 7300. Also, the application server 7100 may obtain data requested by a user or client to read from one of the storage servers 7200 to 7200m through the network 7300. For example, the application server 7100 may be implemented as a web server or a database management system (DBMS).

The application server 7100 may access a memory 7120n or a storage device 7150n included in another application server 7100n through the network 7300, or may access the memories 7220-7220m or storage devices 7250-7250m included in the storage servers 7200-7200m through the network 7300. Accordingly, the application server 7100 may perform various operations on data stored in the application servers 7100 to 7100n or the storage servers 7200 to 7200m. For example, the application server 7100 may execute a command for transferring or copying data between the application servers 7100 to 7100n or the storage servers 7200 to 7200m. In this case, the data may be transferred from the storage devices 7250-7250m of the storage servers 7200-7200m to the memories 7120-7120n of the application servers 7100-7100n directly, or by passing through the memories 7220-7220m of the storage servers 7200-7200m. Data moving through the network 7300 may be encrypted data for security or privacy.

Referring to the storage server 7200 as an example, the interface 7254 may provide a physical connection between the processor 7210 and the controller 7251 and a physical connection between the NIC 7240 and the controller 7251. For example, the interface 7254 may be implemented in a direct attached storage (DAS) method of directly connecting the storage device 7250 using a dedicated cable. Also, for example, the interface 1254 may be implemented by various interface methods such as advanced technology attachment (ATA), serial ATA (SATA), external SATA (e-SATA), small computer small interface (SCSI), serial attached SCSI (SAS), peripheral component interconnection (PCI), peripheral SATA (PCI), PCI express (PCIe), NVM express (NVMe), IEEE 1394, universal serial bus (USB), secure digital (SD) card, multi-media card (MMC), embedded multi-media card (eMMC), universal flash Storage (UFS), embedded universal flash storage (eUFS), or compact flash (CF) card interface.

The storage server 7200 may further include a switch 7230 and a NIC 7240. The switch 7230 may selectively connect the processor 7210 to the storage device 7250 or selectively connect the NIC 7240 to the storage device 7250 under the control of the processor 7210.

In an example embodiment, the NIC 7240 may include a network interface card, a network adapter, and the like. The NIC 7240 may be connected to the network 7300 through a wired interface, a wireless interface, a Bluetooth interface, an optical interface, or the like. The NIC 7240 may include an internal memory, a DSP, a host bus interface, and the like, and may be connected to the processor 7210 or the switch 7230 through the host bus interface. The host bus interface may be implemented as one of the examples of interface 7254 described above. In the example embodiment, the NIC 7240 may be integrated with at least one of the processor 7210, the switch 7230, and the storage device 7250.

In the storage server 7200-7200m or application server 7100-7100n, the processor may transmit a command to the storage device 7130-7130n and 7250-7250m or memory 7120-7120n and 7220-7220m and may be program or read data. In this case, the data may be error-corrected data through an error correction code (ECC) engine. The data may be data bus inversion (DBI) or data masking (DM) processed data, and may include cyclic redundancy code (CRC) information. The data may be encrypted data for security or privacy.

The storage device 7150-7150m and 7250-7250m may transmit a control signal and a command/address signal to the NAND flash memory device 7252-7252m in response to a read command received from the processor. Accordingly, when data is read from the NAND flash memory devices 7252-7252m, the read enable RE signal may be input as a data output control signal and may output data to the DQ bus. A data strobe DQS may be generated using the RE signal. Command and address signals may be latched in the page buffer according to a rising edge or a falling edge of a write enable WE signal.

In the example embodiment, the storage devices 7150-7150m and 7250-7250m may be implemented as a nonvolatile memory device which may perform the on-chip thermal throttling as described with reference to FIGS. 1 to 14.

The controller 7251 may control overall operation of the storage device 7250. In an example embodiment, the controller 7251 may include a static random access memory (SRAM). The controller 7251 may write data to the NAND flash 7252 in response to a write command, or may read data from the NAND flash 7252 in response to a read command. For example, a write command or a read command may be provided from a processor 7210 in a storage server 7200, a processor 7210m in another storage server 7200m, or the processors 7110 and 7110n in the application servers 7100 and 7100n. The DRAM 7253 may temporarily store (buffer) data to be written to the NAND flash 7252 or data read from the NAND flash 7252. Also, the DRAM 7253 may store metadata. Here, the metadata may be user data or data generated by the controller 7251 to manage the NAND flash 7252.

Generally, in a memory such as an SSD, overheating may be prevented through thermal throttling and data reliability may be guaranteed. Generally, depending on the SSD operation and operating environment, a temperature difference between the internal region of the NAND and an external NAND temperature sensor may occur, and in the case of a specific product group, a difference of up to 5.9 degrees may occur, and thermal throttling may be performed earlier than in an actual process, such that there may be loss in data transmission. To prevent entering the thermal throttling easily by accurately sensing the temperature in the NAND, effective thermal throttling may be controlled by applying on-chip DTS, but thermal throttling may be performed by turning on/off the corresponding NAND chip, which may have limitations.

In the example embodiment, a method of thermal throttling in a memory using an On-Chip Digital Temperature Sensor (DTS) may be suggested. Thermal throttling may be performed by controlling the ICC and peak by adjusting the number of serial stages and net time of the high voltage charge pump used for WL setup according to the DTS Code. In the example embodiment, efficient management may be performed as compared to throttling of the existing solution level. In the example embodiment, tR (read time)/tPROG (program time) may be slowed down during throttling. In the example embodiment, suggested is a self-thermal throttling technique for individual NANDs using a NAND internal thermometer to reduce performance degradation during thermal throttling in SSDs.

In the example embodiment individual and self-thermal throttling may be performed using a NAND internal thermometer. In the example embodiment, power consumption may be reduced by adjusting the number of serial stages of the pump+net time according to the temp code using the DTS in the NAND. By performing self-thermal throttling for each individual memory chip, performance deterioration may be reduced. Also, by increasing current efficiency through pump series operation control, power consumption may be reduced, which may be more efficient than the general speed control method.

Meanwhile, the example embodiment may be applied to a nonvolatile memory device receiving temperature information from an external device (e.g., a controller) without including a DTS (Digital Temperature Sensor) and performing on-chip thermal throttling using the received temperature information. That is, the nonvolatile memory device in the example embodiment may control the number of pump stages or the timing of pump voltage generation using temperature information received from an external entity for thermal throttling.

Meanwhile, the example embodiment may be applicable to a nonvolatile memory device and also to a volatile memory device performing on-chip thermal throttling. In a memory such as SSD, overheating may be prevented by thermal throttling and data reliability may be assured. When thermal throttling is performed at a general solution level, thermal throttling may be performed by turning on/off the corresponding memory chip, but in the example embodiment, thermal throttling may be performed in the chip using on-chip DTS, and ICC and Peak may be managed by controlling the current efficiency and slope of high-voltage pumps, such that thermal throttling may be performed efficiently.

According to the aforementioned example embodiments, the nonvolatile memory device, the storage device including the same, and the method of operating the same may, by adjusting the number or timing of serial stages of the charge pump used for wordline setup according to the output of a digital temperature sensor (DTS), control peak/average current.

Also, the nonvolatile memory device, the storage device including the same, and the method of operating the same may enable optimal thermal throttling by controlling current consumption through an internal temperature sensor of the memory chip.

Aspects of the present invention are not limited to nonvolatile memory devices but can also be applied to volatile memory devices that perform on-chip thermal management. In memory devices such as SSDs, overheating is prevented through thermal throttling to ensure data reliability. In conventional solutions, thermal throttling is achieved by turning on/off the corresponding memory chip. However, aspects of the present invention introduce the concept of on-chip thermal throttling using a DTS (digital temperature sensor). Aspects of the present invention manage ICC (instantaneous current consumption) and peak current through current efficiency and slope control of high-voltage pumps, allowing for more efficient thermal throttling than before.

While the example embodiments have been illustrated and described above, modifications and variations could be made without departing from the scope of the present disclosure as defined by the appended claims as apparent to those skilled in the art that.

1. A nonvolatile memory device, comprising:
a charge pump circuit including pump units connected in series configured to receive an external voltage and to perform a charge pumping operation, and configured to output a pump voltage by forming stages corresponding to the number of pump units connected in series in response to stage control signals;
a switching circuit configured to control the charge pump circuit to output pumping voltages of the pump units in response to switch control signals;
a stage controller configured to output the stage control signals and the switch control signals according to a temperature code; and
a digital temperature sensor configured to generate the temperature code.

2. The nonvolatile memory device of claim 1, wherein the stage controller varies the number of stages according to the temperature code.

3. The nonvolatile memory device of claim 1, wherein the stage controller forms stages in which the number of pump units increasing per unit time is the same.

4. The nonvolatile memory device of claim 1, wherein the stage controller forms stages in which the numbers of pump units increasing per unit time is different.

5. The nonvolatile memory device of claim 1, wherein the stage controller varies the number of pump units included in a starting stage according to the temperature code.

6. The nonvolatile memory device of claim 1,
wherein the stage controller outputs the switch control signals per unit time, and
wherein the unit time varies according to the temperature code.

7. The nonvolatile memory device of claim 1, wherein a read time (tR) or a program time (tPROG) varies according to the temperature code.

8. The nonvolatile memory device of claim 1, wherein the digital temperature sensor includes:
a temperature detector configured to generate a voltage signal or a current signal corresponding to a temperature of a predetermined region of the nonvolatile memory device; and
a code generator configured to generate the temperature code corresponding to the voltage signal or the current signal.

9. The nonvolatile memory device of claim 1, further comprising:
a wordline voltage generator configured to generate a wordline voltage using the pump voltage.

10. The nonvolatile memory device of claim 1, wherein the stage controller is activated in response to a command received from an external device.

11. A method of operating a nonvolatile memory device, the method comprising:
sensing a temperature by a digital temperature sensor;
determining a pump stage in response to a temperature code corresponding to the sensed temperature; and
generating a wordline voltage using a pump voltage according to the determined pump stage.

12. The method of claim 11, wherein the determining the pump stage includes determining a number of pump units connected in series.

13. The method of claim 11, wherein the determining the pump stage further includes changing the pump stage per unit time.

14. The method of claim 13, wherein the determining the pump stage further includes varying the unit time according to the temperature code.

15. The method of claim 11, wherein the generating a wordline voltage includes generating the wordline voltage by dividing the pump voltage by a resistance.

16. A storage device, comprising:
at least one nonvolatile memory device; and
a controller configured to control the at least one nonvolatile memory device,
wherein the at least one nonvolatile memory device includes:
a plurality of memory blocks including a plurality of memory cells connected to wordlines and bitlines;
a digital temperature sensor configured to sense a temperature of at least one predetermined region of the at least one nonvolatile memory device and to generate a temperature code; and
a control logic circuit configured to perform an on-chip thermal throttling operation according to the temperature code, and
wherein the on-chip thermal throttling operation controls timing of a wordline voltage applied to at least one of the wordlines.

17. The storage device of claim 16, further comprising:
a voltage generator configured to generate the wordline voltage,
wherein the voltage generator includes charge pumps connected in series.

18. The storage device of claim 17, wherein the control logic circuit forms stages corresponding to the number of charge pumps connected in series per unit time.

19. The storage device of claim 18, wherein the control logic circuit adjusts the unit time or varies the number of stages according to the temperature code.

20. The storage device of claim 16, wherein the controller performs an off-chip thermal throttling operation based on temperature information.

21-25. (canceled)
